(19) United States
(12) Patent Application Publication
(10) Pub. No.: US 2017/0069468 A1
(43) Pub. Date: Mar. 9, 2017

(54) Device for Processing Plasma with a Circulation of Process Gas in Multiple Plasmas

(71) Applicant: MEYER BURGER (GERMANY) AG, Hohenstein-Ernstthal (DE)

(72) Inventors: Hermann SCHLEMM, Milda (DE); Mirko KEHR, Amtsberg OT Dittersdorf (DE); Erik ANSORGE, Chemnitz (DE); Daniel DECKER, Ehrenfriedersdorf (DE)

(21) Appl. No.: 15/122,638

(22) PCT Filed: Mar. 3, 2015
(86) PCT No.: PCT/EP2015/054334

§ 371 Date: Aug. 31, 2016

(30) Foreign Application Priority Data
Mar. 7, 2014 (EP) 14158269.2

(51) Int. Cl. H01J 37/32; C23C 16/455; C23C 16/50; C23C 16/44

(52) U.S. Cl. CPC H01J 37/32449; H01J 37/32834; H01J 37/32779; H01J 37/32871; C23C 16/4412; C23C 16/45512; C23C 16/45593; C23C 16/50; H01J 2237/3321; H01J 2237/334

(57) ABSTRACT

The device for plasma processing as per the invention is comprised of a processing chamber with at least two plasma processing zones with process gas flowing through them, a gas inlet that is suitable for feeding the process gas to the at least two plasma processing zones, and a gas outlet that is suitable for discharging exhaust gas from the processing chamber, as well as a circulation unit with a circulation line and a circulation pump, wherein the circulation unit is suitable for feeding at least a portion of the exhaust gas into the gas inlet and wherein the exhaust gas that is fed into the gas inlet is a mixture of gases that are discharged from at least two of the plasma processing zones. Because of the mixture of exhaust gases from at least two of the plasma processing zones and their renewed feeding into the gas inlet, the components of the process gas from the at least two plasma processing zones that have already been converted, but also those that have not yet been converted, are mixed and a homogenization of the process gas is therefore achieved that is fed into the plasma processing zones. This reduces the inhomogeneity of the plasma processing among individual substrates that arises from differences in the plasma process in different plasma processing zones.

### CROSS REFERENCE TO RELATED APPLICATIONS

This application is the U.S. national stage of International Application No. PCT/EP2015/054334, filed on Mar. 3, 2015. The international application claims the priority of EP 14158269.2 filed on Mar. 7, 2014; all applications are incorporated by reference herein in their entirety.

### BACKGROUND

The invention relates to a device for processing plasma with low-temperature plasmas that have multiple plasma processing zones in a processing chamber, in which a portion of the exhaust gas that is discharged from the processing chamber is added back to the process gas for the plasma processes.

Plasma processes are used, as examples, in the production of solar cells, microelectronics and the refinement of substrate surfaces (e.g. glass) with regard to the deposition or removal of layers or particles or with regard to the doping of layers, for instance via plasma-immersion ion implantation. To increase the throughput in the plasma processing, batch systems are used in which several substrates are simultaneously treated. In so doing, the substrates with the surface to be processed can be arranged next to or on top of one another. Systems are known from U.S. Pat. No. 4,287,851 B and EP 0 143 479 A1 in which a plasma processing zone, which is operated separately from the other plasma processing zones, is assigned to each substrate.

The process gas that is used during the plasma processing is either introduced in only one place in the processing chamber and is distributed to the individual plasma processing zones from there or is fed into the individual plasma processing zones via separate outlet openings (e.g. nozzles) in each case. In so doing, the process gas advantageously flows through the plasma processing zone.

Different processing results can come about over the multitude of substrates that are simultaneously processed because of differences in the plasma-production conditions, in the boundary conditions for a particular substrate (for instance ambient temperature) and other instances of inhomogeneity in the processing chamber. They can constitute, as examples, different deposition or etching rates or different compositions of the deposited layers or different doping amounts.

Furthermore, in the case of large substrates, an inhomogeneity of the process comes about over the whole lateral extension of the substrate because the process gas changes in terms of its composition over its transport path through the plasma processing zone. The number of reactive components decreases, for example, because of the reactions of components of that type that have taken place over the length of the substrate in the direction of the process gas flow. The layer thickness based on deposition or removal therefore also decreases in this substrate direction.

A pulsing of the plasmas that are produced is a known remedy to the last problem. In so doing, the plasmas are only ignited for a short period of time with a short pulse; the plasmas are shut off for most of the time (approx. 90%) in a cycle. New, unspent process gas can be distributed over the entire substrate during this down time, so equal deposition or etching rates can be achieved at all points of the substrate during the period in which the plasma is ignited. This leads to a substantial increase in the processing time, however, because only 10% of the overall time is effectively used.

### SUMMARY

The device for plasma processing as per the invention is comprised of a processing chamber with at least two plasma processing zones with process gas flowing through them, a gas inlet that is suitable for feeding the process gas to the at least two plasma processing zones, and a gas outlet that is suitable for discharging exhaust gas from the processing chamber, as well as a circulation unit with a circulation line and a circulation pump, wherein the circulation unit is suitable for feeding at least a portion of the exhaust gas into the gas inlet and wherein the exhaust gas that is fed into the gas inlet is a mixture of gases that are discharged from at least two of the plasma processing zones. Because of the mixture of exhaust gases from at least two of the plasma processing zones and their renewed feeding into the gas inlet, the components of the process gas from the at least two plasma processing zones that have already been converted, but also those that have not yet been converted, are mixed and a homogenization of the process gas is therefore achieved that is fed into the plasma processing zones. This reduces the inhomogeneity of the plasma processing among individual substrates that arises from differences in the plasma process in different plasma processing zones.

### DETAILED DESCRIPTION

The objective of the instant invention is to consequently provide a device for plasma processing of multiple substrates with several plasma processing zones that is suitable for reducing instances of inhomogeneity of plasma processing among individual substrates that rise because of differences of the plasma processing in different plasma processing zones. Furthermore, an objective of the instant invention is to provide a device for plasma processing that also reduces instances of inhomogeneity of plasma processing over a whole substrate.

This problem is solved by the device according to claim 1. Advantageous embodiments are found in the subordinate claims.

The device for plasma processing as per the invention is comprised of a processing chamber with at least two plasma processing zones with process gas flowing through them, a gas inlet that is suitable for feeding the process gas to the at least two plasma processing zones, and a gas outlet that is suitable for discharging exhaust gas from the processing chamber, as well as a circulation unit with a circulation line and a circulation pump, wherein the circulation unit is suitable for feeding at least a portion of the exhaust gas into the gas inlet and wherein the exhaust gas that is fed into the gas inlet is a mixture of gases that are discharged from at least two of the plasma processing zones.

In general, the terms “gas”, “process gas” or “exhaust gas” in this application are understood to mean any kind of gas or gas mixtures that are suitable for plasma processing or that arise during it.

The gas inlet is realized, for instance, by at least one opening connected to a gas line in the wall of the processing chamber, by at least one gas line (pipe) projecting into the processing chamber or by an intake chamber that is connected to at least one gas line and that has one or more openings from which the process gas flows into the processing chamber. In the same way, the gas outlet is realized, for instance, by at least one opening connected to an exhaust gas line in the wall of the processing chamber, by at least one exhaust gas line (pipe) projecting into the processing chamber or by an outlet chamber that is connected to at least one exhaust gas line and that has one or more openings through which the process gas flows out of processing chamber.

As already described above, different plasma processing zones can have different rates of conversion of the components of the process gas, for instance into radicals, ions or reaction products. Because of the mixture of exhaust gases from at least two of the plasma processing zones and their renewed feeding into the gas inlet, the components of the process gas from the at least two plasma processing zones that have already been converted, but also those that have not yet been converted, are mixed and a homogenization of the process gas is therefore achieved that is fed into the at least two plasma processing zones. This reduces the inhomogeneity of the plasma processing among individual substrates that arises from differences in the plasma process in different plasma processing zones. In other words: The deposition rate or etching rate or other processing rates of the substrates are homogenized, i.e. balanced out, by the thorough mixing of the process gases over all of the substrates.

Furthermore, the process gas is made better use of for the respective plasma process because, on the one hand, components of the process gas that have not yet been used for the layer deposition or removal are fed into the plasma process once again and, on the other hand, the process gas will thereby already contain reactive components or activated components that require less activation for the desired reaction than a process gas that has not yet been activated up to that point via a plasma. Both a reduction in the gas consumption, meaning the consumption of fresh process gas, and an increase in the deposition or etching rate for the plasma process can be achieved because of that.

The circulation unit preferably comprises a control valve, wherein the control valve and the circulation pump are designed in such a way that the ratio of the gas flow of the exhaust gas fed into the gas inlet via the circulation line to the gas flow of a gas differing from the exhaust gas that is fed into the gas inlet is in a range smaller than 100. A typical and preferred value for the ratio is between 8 and 12, with a special preference for 10. This means that a gas flow greater by multiples than the gas flow freshly fed into the plasma processing is removed from the exhaust gas by the circulation unit and fed back into the gas inlet and therefore the plasma processing. The flow rate of the process gas through the plasma processing zones is significantly increased because of that, and the retention time of the process gas in the respective plasma processing zone is significantly reduced, for instance by approximately 10-fold. The degree of plasma-chemical degradation of the process gas while passing through the respective plasma processing zone also drops with that; a more homogeneous composition of the components of the process gas in the plasma processing zone is achieved over the length of the substrate in the direction of flow of the gas because of that and, in the end, a more homogeneous thickness of the deposited or removed layer is achieved over the whole extension of the substrate. In other words: The processing of each substrate is homogenized over its whole extension in the direction of the gas flow. Moreover, the above-mentioned effect of a renewed feed-in of gas components that have already been activated is reinforced, which leads to a further increase in the deposition or etching rate.

Outstanding homogenization of the layer thicknesses and/or other layer properties, for instance optical or electrical properties such as transparency, refraction index, electrical conductivity etc., is achieved over the whole extension of a substrate in the direction of the gas flow and over a multitude of substrates because of the effects of the gas feedback that were described; the deviations of layer thickness or of the other layer properties are in a range of a few percentage points, for instance less than or equal to ±4%.

In one embodiment of the device as per the invention, the circulation line is connected to a gas supply line that is suitable for feeding a gas differing from the exhaust gas into the gas inlet. This gas is a fresh gas or gas mixture that can contain one, several or all of the components of the process gas and serves to start the plasma process and to replace the components of the process gas that are consumed by the plasma processing. The freshly fed-in gas and the exhaust gas that is fed back into the plasma process via the circulation line are therefore already mixed in the gas supply line that is connected to the gas inlet, and only one gas supply line is required to feed both the freshly fed-in gas and the recirculated exhaust gas into the processing chamber.

In a preferred embodiment, the gas inlet is connected to two gas supply lines; a first gas supply line is directly connected to the circulation line, and a second gas supply line is connected to a device for providing a gas differing from the exhaust gas. The second gas supply line is therefore suitable for feeding a fresh gas or a fresh gas mixture to the process gas, so components of the process gas that are consumed by the plasma processing can be replaced.

The gas inlet is preferably designed in the form of a gas inlet mixing chamber that has at least two discharge systems each with one or more openings. Each discharge system is assigned to one of the at least two plasma processing zones here, so the process gas flows out of the openings of the respective discharge system to the assigned plasma processing zone. The multiple openings of a discharge system preferably have an arrangement and size to the effect that the process gas is fed into the plasma processing zone evenly or in a manner adapted to the plasma conditions of the plasma processing zone. As an example, the openings can be arranged at a smaller distance to one another in the edge area of the plasma processing zone or can have different key values than the openings in a central area of the plasma activation zone. Furthermore, the individual discharge systems, meaning discharge systems differing from one another assigned to different plasma processing zones, can have different arrangements and/or key values of the openings. The openings of the discharge systems preferably have the same key value. In addition to the defined supply of the process gas to the individual plasma processing zones, the inlet chamber is also suitable for ensuring a mixture of the exhaust gas fed in via the circulation line and the fed-in gas differing from the exhaust gas. This is especially advantageous if the exhaust gas fed in via the circulation line and the fed-in gas differing from the exhaust gas are fed into the gas inlet via two gas supply lines that are separated from one another. The gas inlet mixing chamber can be arranged outside on the wall of the processing chamber or inside of the processing chamber, in contact with the wall or spaced apart from it.

If the gas inlet is connected to two gas supply lines, the first serving to feed in the exhaust gas and a second one serving to provide a gas differing from the exhaust gas, as described above, the gas inlet mixing chamber will have at least two sub-chambers in an especially preferred embodiment; each sub-chamber will have a separate discharge system from which the process gas flows to at least one plasma processing zone and which is assigned in each case to at least one of the plasma processing zones. Every sub-chamber is assigned to at least one dispensing unit here that is suitable for separately adjusting the quantity of fed-in exhaust gas or the quantity of the fed-in gas differing from the exhaust gas for the respective sub-chamber.

The gas outlet is preferably realized by a gas outlet mixing chamber that has at least two intake systems, each with one or several openings through which the exhaust gas from the plasma processing zones flows into the gas outlet mixing chamber; each intake system is assigned to one of the at least two plasma processing zones. The multiple openings of an intake system preferably have an arrangement and size to the effect that the process gas is discharged from the assigned the plasma processing zone evenly or in a manner adapted to the plasma conditions of the plasma processing zone. What has already been stated with regard to the discharge systems and their openings applies here. The openings of the at least two intake systems preferably have the same key value. The gas outlet mixing chamber can be arranged outside on the wall of the processing chamber or inside of the processing chamber, in contact with the wall or spaced apart from it.

In a preferred embodiment, the gas outlet is connected to a device for discharging gas through an exhaust gas line and the circulation line is connected to the exhaust gas line. Only one exhaust gas line connected to the gas outlet is therefore necessary. The device for gas discharge, for instance a vacuum pump, serves here, on the one hand, to set a defined pressure in the processing chamber and to also discharge the exhaust gas from the gas outlet, and therefore serves to regulate the supply of the process gas to the process chamber.

In another preferred embodiment, the gas outlet is connected to a device for gas discharge through an exhaust gas line and, separately from that, connected to the circulation line. This means that the gas outlet is connected to two gas discharge lines, the first of which is the exhaust gas line and the second of which is the circulation line. This makes it possible to adapt both the exhaust gas line and circulation line and also the device for gas discharge and the circulation pump to the parameters and purity requirements to be set. As an example, the circulation pump is not supposed to bring about any impurities of the recirculated exhaust gas; greater demands can be placed on the circulation pump than on the vacuum pump connected to the exhaust gas line because of that.

The circulation unit preferably contains a dust-collection device that is preferably arranged in front of the circulation pump in the circulation line.

As a further preference, the circulation unit contains a device for removing specific components of the exhaust gas, especially gaseous components. That can be reaction products that are no longer used in the plasma process, for instance.

In a preferred embodiment, the gas inlet and the gas outlet are identical and the device for plasma processing has a changeover unit that is suitable, in a first switching state, to supply the gas inlet with exhaust gas fed in through the circulation line and the fed-in gas differing from the exhaust gas, and to discharge the exhaust gas from the gas outlet, and, in a second switching state, to supply the gas outlet with exhaust gas fed in through the circulation line and the fed-in gas differing from the exhaust gas, and to discharge the exhaust gas from the gas inlet. The device for plasma processing is therefore suitable for bringing about a change in the gas circulation direction of the gas flow in the processing chamber and the plasma processing zones. The thickness of the layer that has been deposited or removed can therefore be homogenized, i.e. balanced, in an even better way over the whole extension of the substrate. The changeover unit is preferably comprised of two valve groups, each with two valves; the valves of the first valve group are switched in an opposite way with respect to the valves of the second valve group in each case. One valve of each valve group is located in the exhaust gas branch of the device, and the other respective valve of each valve group is located in the supply branch of the device. The changeover unit is preferably suitable for changing the switching state and therefore the direction of gas circulation between 5 and 25 times per plasma processing event. A plasma processing event is, for instance, the coating of a substrate with a specified layer thickness or the removal of a specified thickness of a layer from a substrate.

The device for plasma processing preferably has, moreover, a device for moving an arrangement of substrates that are processed in the plasma processing zones along a first direction in the processing chamber. The processing chamber is comprised of several gas inlets and several gas outlets here; the gas inlets and the gas outlets are arranged in an alternating fashion along the first direction on one side of the processing chamber. As an example, the gas inlets and gas outlets are arranged on the upper wall of the processing chamber; the substrates are laterally arranged next to one another and move along beneath the plasma processing zones that are arranged along the first direction between the respective gas inlets and gas outlets. In so doing, the process gas flows to the substrate arrangement, but not through the substrate arrangement. This corresponds to a so-called in-line plant with flat, individual substrates laterally arranged next to one another in which the process gas flows in a direction along the direction of movement of the substrates. The exhaust gas from at least two gas outlets is mixed by the circulation unit and fed back into the gas inlets.

In another preferred embodiment, the gas inlet and the gas outlet are arranged on opposite sides of the processing chamber. The plasma processing zones can be arranged laterally next to one another or preferably vertically stacked on top of one another between the gas inlet and the gas outlet here.

The device for plasma processing preferably has, moreover, a device for moving an arrangement of substrates that are processed in the plasma processing zones along a first direction in the processing chamber. The processing chamber is comprised of several gas inlets and several gas inlets that are assigned to them here; the gas inlets and the gas outlets are arranged along the first direction in such a way that a specific gas inlet is arranged on one side of the processing chamber that extends along the first direction and a gas outlet that is assigned to this specific gas inlet is arranged on the opposite side of the processing chamber. In so doing, the substrates in the substrate arrangement are arranged laterally next to one another or preferably vertically stacked on top of one another between a specific gas inlet and a gas outlet arranged to be opposite it so that the process gas flows through the substrate arrangement and the plasma processing zones assigned to the respective gas inlet and gas outlet. This corresponds to an in-line plant in which substrate stacks can also be processed where the process gas flows in a direction that is vertical with respect to the direction of movement of the substrates. In the process, the substrates can be moved during the plasma processing or can be processed in a quasi-stationary manner. In the second case, the substrates are moved from a position between a first pair made up of a gas inlet and an assigned gas outlet to a different position between a second pair made up of a gas inlet and an assigned gas outlet in the processing chamber, but they remain without movement at the respective position during the plasma processing.

The gas outlet preferably discharges the exhaust gas in the process from at least two plasma processing zones that are supplied with process gas by the assigned gas inlet, mixes this and feeds it back to at least the assigned gas inlet.

In a preferred embodiment, the device for plasma processing is comprised of the same number of circulation units as there are pairs of gas inlets and gas outlets assigned to them; a circulation unit is assigned to every specific pair made up of a gas inlet and an assigned gas outlet. The exhaust gases from a specific gas outlet are therefore exclusively fed into the assigned gas inlet by the assigned circulation unit.

Alternatively, the exhaust gases of several gas outlets are mixed with one another and fed back into at least one, preferably several, gas inlets. In an especially preferred embodiment, the exhaust gases from all of the gas outlets are mixed and fed into all of the gas inlets. Only one circulation unit is required for this design form.

In an especially preferred embodiment of the device for plasma processing, the gas inlets and the accompanying gas outlets of two pairs of gas inlets and gas inlets assigned to them that are arranged in back of one another in the first direction are arranged in such a way that the gas inlet of the one pair is located on the same side of the processing chamber as the gas outlet of the other pair. At least two gas inlets and two gas outlets are thereby arranged in an alternating fashion on the same side of the processing chamber along the first direction. Instances of inhomogeneity over the extension of the substrates in the direction of flow of the process gas are balanced out with this arrangement, because the direction of flow of the process gas alternatives between the two pairs of gas inlets and assigned gas outlets.

The device for plasma processing as per the invention will be explained below with the aid of several examples without limiting the device to these examples. In particular, it is possible to combine aspects with one another that are described with reference to different examples as long as this is not expressly ruled out.

### BRIEF DESCRIPTION OF THE DRAWINGS

FIG. 1A shows a cross-section of a first embodiment of the device for plasma processing as per the invention in which the gas inlet is realized by an intake chamber and the circulation line is connected to a gas supply line that is suitable for supplying a gas that differs from the exhaust gas to the gas inlet. Furthermore, the first embodiment only has one exhaust gas line via which the exhaust gas is discharged from the gas outlet and which is connected to the circulation line.

FIG. 1b schematically shows the progression of thickness of a deposited layer over the extension of a substrate throughout the direction of gas flow for a conventional process without gas recirculation and a process using the device as per the invention.

FIG. 1C shows a section from FIG. 1A, wherein the homogenization of the processing rates over a multitude of substrates is elucidated with the aid of differential gas volumes.

FIG. 2 shows a cross-section of a second embodiment of the device for plasma processing as per the invention in which the gas inlet realized by an intake chamber is connected to two gas supply lines, one of which is suitable for supplying a gas differing from the exhaust gas to the gas inlet and the other one is the circulation line. Moreover, the second embodiment has two exhaust gas lines via which the exhaust gas is discharged from the gas outlet; one of them is the circulation line.

FIG. 3 is an embodiment of the gas inlet in which the gas inlet is designed as a mixing chamber with several sub-chambers. The quantity of fed-in exhaust gas and the quantity of fed-in gas differing from the exhaust gas can be separately set here for each sub-chamber with the aid of dispensing units.

FIG. 4 schematically shows a third embodiment of the device for plasma processing as per the invention in which the circulation unit further contains a dust-collection device and a device for removing specific gaseous components of the exhaust gas.

FIG. 5 schematically shows the structure of a fourth embodiment of the device for plasma processing as per the invention in which the direction of circulation of the gases can be changed.

FIG. 6a to FIG. 6C show specific examples of the production of the plasma and the electrical connection of the substrate holders, wherein FIG. 6a shows an example of unpulsed plasma production, FIG. 6B shows an example of pulsed plasma production and FIG. 6C shows an example of remote plasma production.

With regard to FIGS. 7A and 7B, a fifth embodiment of the device for plasma processing as per the invention is elucidated in which the substrate arrangement is guided along beneath the process gas flow. FIG. 7A shows a top view of the system here, whereas FIG. 7B shows a cross-section through the system in the direction of movement of the substrate arrangement.

FIG. 8 shows a sixth embodiment of the device for plasma processing as per the invention in which the process gas flows through the substrate arrangement and the cross-section of the substrate arrangement corresponds to the cross-section shown in FIG. 1A, as an example.

### DETAILED DESCRIPTION OF THE PREFERRED EMBODIMENTS

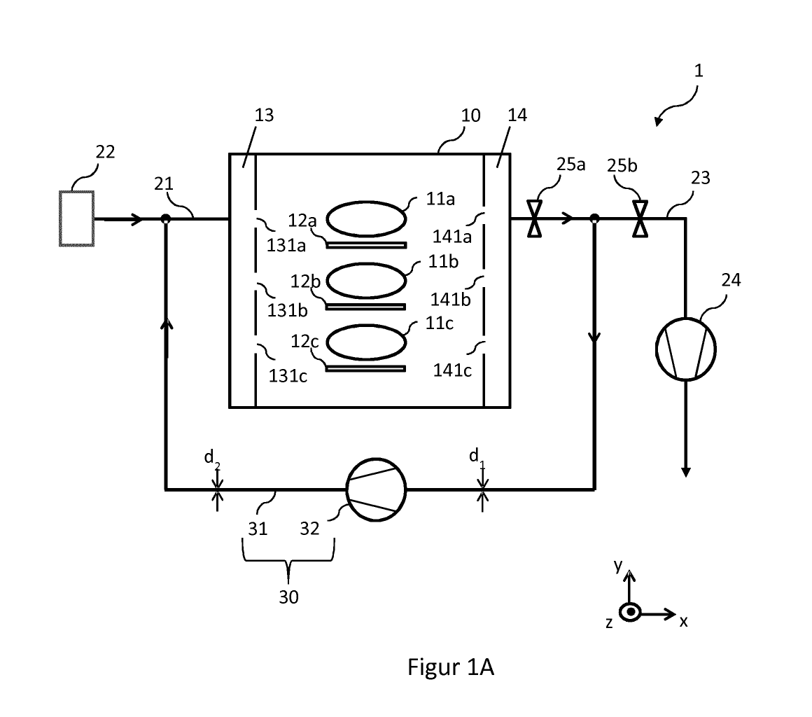

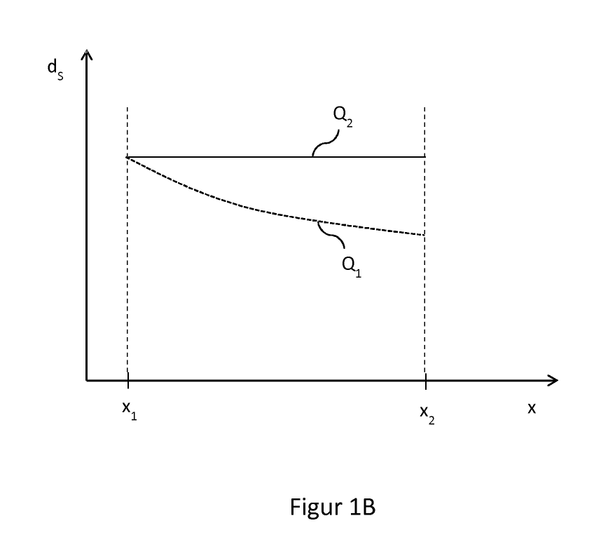

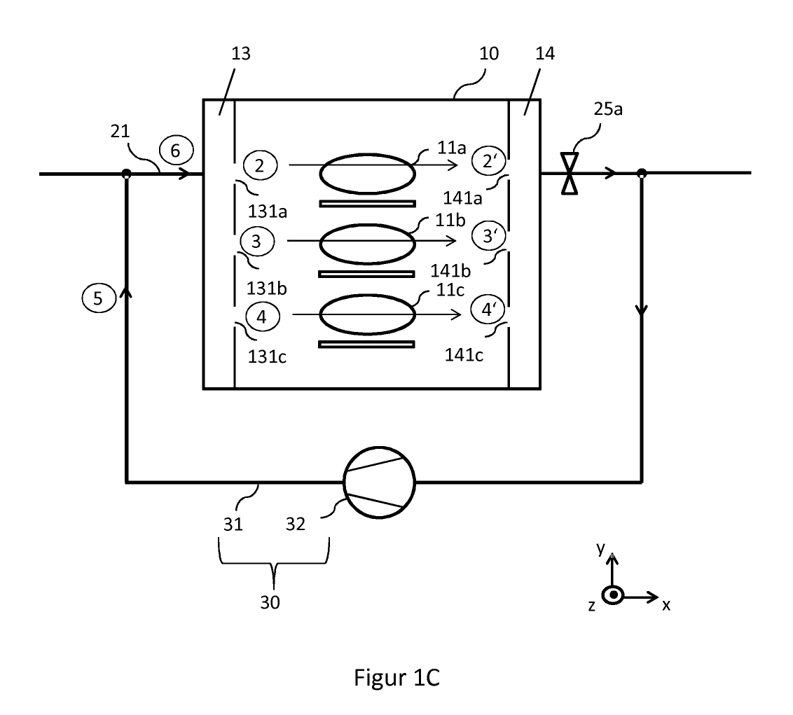

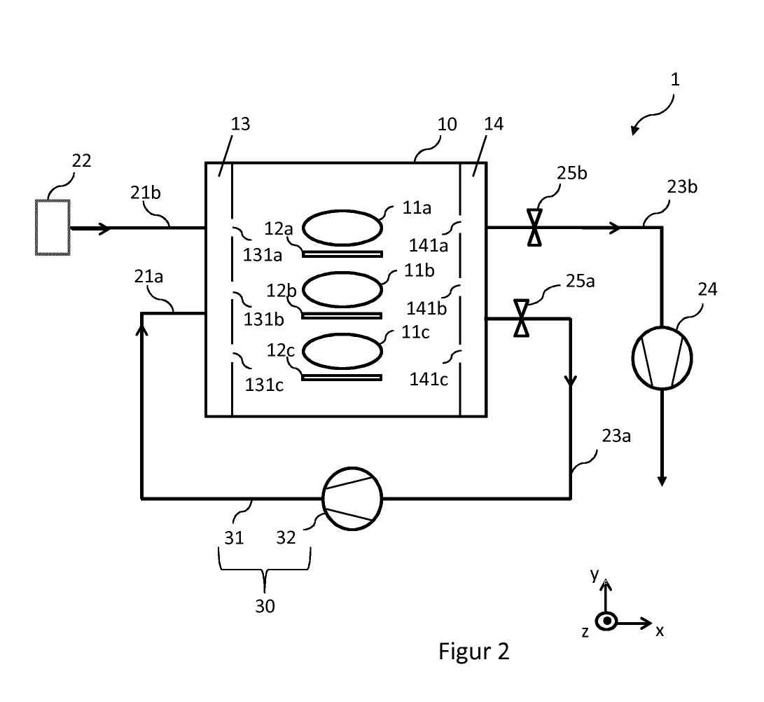

A first embodiment of the device (1) for plasma processing as per the invention is shown in FIG. 1A in a cross-section along the x-y plane in a three-dimensional Cartesian coordinate system. The device (1) is comprised of a processing chamber (10), a gas supply line (21), a gas provision unit (22) connected to the gas supply line (21), an exhaust gas line (23), a pump (24) connected to the exhaust gas line (23) and a circulation unit (30).

The processing chamber (10) has several plasma processing zones (11a to 11c), as well as a gas inlet (13) that is realized in the form of a gas inlet mixing chamber and a gas outlet (14) that is realized in the form of a gas outlet mixing chamber. The processing chamber (10) has three plasma processing zones (11a to 11c) in the embodiment shown in FIG. 1. In other embodiments, only two plasma processing zones or more than three plasma processing zones can also be arranged between the gas inlet (13) and the gas outlet (14). The plasma processing zones serve in the plasma processing of substrates (12a to 12c) that are arranged in each case beneath an assigned plasma processing zone (11a to 11c) in the case that is shown. In other embodiments, the substrates can also be arranged above, inside of or on the side of the respective plasma processing zone. The substrates are vertically stacked on top of one another in the case that is shown, meaning along the y axis and perpendicular to their lateral extension, in a so-called substrate stack. In other embodiments, several substrates can also be laterally arranged next to one another, meaning along the x axis and along the z axis. The specific plasma processing zones can then also be laterally arranged next to one another. A combination of the lateral and vertical arrangements of several substrates next to one another or on top of one another is also possible.

The gas inlet (13) is arranged on a first side of the processing chamber (10), whereas the gas outlet (14) is arranged on a second side of the processing chamber; the second side of the processing chamber is opposite the first side. Both the intake chamber of the gas inlet (13) and the outlet chamber of the gas outlet (14) are arranged inside of the processing chamber (10), meaning on the inside of the wall of the processing chamber (10). The substrates (12a to 12c) are arranged between the first and second sides of the processing chamber (10) so that a process gas flowing between the gas inlet and the gas outlet will flow through the substrate arrangement, meaning the entirety of the substrates. The gas inlet (13) has several discharge openings (131a to 131c) from which the process gas flows to the plasma processing zones (11a to 11c), whereas the gas outlet (14) has several intake openings (141a to 141c) through which the exhaust gas that is being discharged from the plasma processing zones (11a to 11c) flows into the gas outlet. Three discharge openings (131a to 131c) and three intake openings (141a to 141c) exist in the embodiment shown in FIG. 1. Although this cannot be seen in the cross-section shown in FIG. 1, several discharge openings and several intake openings are arranged along the z direction of the processing chamber. The discharge openings from which the process gas flows to a specific plasma processing zone (11a to 11c) form a discharge system here that is assigned to the specific plasma processing zone. In the same way, the intake openings through which the exhaust gas being discharged from a specific plasma processing zone (11a to 11c) flows form an intake system that is assigned to the specific plasma processing zone. The discharge openings of a specific discharge system and the intake openings of a specific intake system are each arranged in the same position with regard to the y axis.

In other embodiments, the number of discharge openings and the number of intake openings can also differ from three, differ from one another and even be different for different plasma processing zones. Furthermore, the number of discharge openings for various discharge systems, the number of intake openings for various intake systems, as well as the vertical position of the discharge openings in a specific discharge system and the vertical position of the intake openings in a specific intake system, meaning their position with reference to the y axis, can be different.

The gas inlet mixing chamber has a sufficiently large cross-section in the x-y plane and therefore a sufficiently small key flow value in the interior, so the process gas can be fed into the multiple plasma processing zones from the discharge openings (131a to 131c) in an equally distributed way. The discharge openings (131a to 131c) advantageously have small cross-sections and dimensions such that the effect of gas interblocking arises in them.

The gas inlet (13) is connected to the gas supply line (21) via which the process gas is fed into the gas inlet (13). The process gas is comprised here of a mixture of fresh gas that is provided by the gas provision unit (22) and of exhaust gas that is fed back into the gas inlet (13) from the gas outlet (14) via the circulation unit (30). The fresh gas and the exhaust gas are already mixed in the gas supply line (21) in the process and, moreover, in the gas inlet mixing chamber of the gas inlet (13). The quantity of fresh gas is regulated via a dispensing unit, for instance a mass flow controller, in the gas provision unit (22).

The gas outlet (14) is connected to an exhaust gas line (23) to which a pump (24) is connected. The pump (24) serves, on the one hand, to suction off the exhaust gas arising during the plasma processing and, on the other hand, to set a defined pressure in the processing chamber (10) together with the control valves (25a, 25b) arranged in the exhaust gas line (23). In the process, the exhaust gases from different plasma processing zones (11a to 11c) are mixed in the gas outlet mixing chamber of the gas outlet (14) and in the exhaust gas line (23).

The circulation unit (30) is comprised of a circulation line (31) and a circulation pump (32). The circulation line (31) is connected to the exhaust gas line (23) and the gas supply line (21) in the first embodiment of the device for plasma processing as per the invention, so the gas inlet (13) is only connected to the gas supply line (21) and the gas outlet (14) is only connected to the exhaust gas line (23). A portion of the exhaust gas is fed back into the process gas with the aid of the circulation unit (30); the proportion of exhaust gas that is fed back in again with respect to the overall exhaust gas is set with the control valves (25a, 25b). The proportion of exhaust gas that is fed back in again is therefore also regulated with respect to the overall process gas, which is equal to or greater than the flow of fresh gas. As an example, a gas flow that is 10 times larger than the gas flow of the fresh gas is removed from the exhaust gas and fed into the gas inlet again. A Roots pump that generates sufficient overpressure for the gas circulation with a compression ratio of about 10 is suitable as a circulation pump (32). Since Roots pumps with suction power in the range of 250 to 25,000 m³/h are available, very large processing chambers can also be provided with adequate gas circulation. Roots pumps are advantageously used in a design with semiconductor-level purity, so only very small leakage rates additionally arise in the circulation unit (30) and contamination of the process gas with gearbox oil from the Roots-pump shaft bearings, for instance, is prevented. The diameter (d₁) of the circulation line (31) in front of the circulation pump (32) in the direction of the pumped gas can be greater than the diameter (d₂) of the circulation line (31) after the circulation pump (32) in the direction of the pumped gas here.

FIG. 1B schematically shows the progression of the thickness ds of a deposited layer over the whole extension of a substrate in the direction of gas flow (x direction). The substrate or the surface of the substrate treated during the plasma process extends here from a first point x₁ to a second point x₂ along the x direction shown in FIG. 1A. The progressions of thickness for a conventional process without gas recirculation in which there is a relatively small amount of gas flow throughput Q₁ are shown, and those for a process as per the invention with a correspondingly large amount of gas flow throughput Q₂ are shown, as comes about with the aid of the gas circulation in the device as per the invention. A homogeneous composition of the process gas for a specific point xi is assumed, i.e. the composition of the process gas in the z direction is homogenous, with regard to the extension of the substrate crosswise to the direction of gas flow, i.e. in the z direction.

The layer thickness ds decreases in the x direction in the conventional process, because the process gas undergoes plasma-chemical degradation in the plasma processing zone with the low flow velocity and the deposition rate drops with an increasing share of breakdown products. Furthermore, other layer parameters, for instance optical or electrical properties such as transparency, refraction index, electrical conductivity etc. can also change.

When the device as per the invention is used, the process gas is moved through the plasma processing zone with a greater, for instance ten-fold, flow velocity caused by the gas circulation in the circulation unit (30). The plasma-chemical degradation of the process gas in the plasma processing zone is dropped so low with this increased gas flow throughput Q₂ that the deposition rate remains virtually unchanged. The layer thickness ds and the other layer parameters will therefore be homogenized, i.e. uniformly produced, over the whole extension of the substrate in the x direction.

An explanation is provided with the aid of FIG. 1C, which shows a section of FIG. 1A, as to how the processing of different substrates in a substrate arrangement with up to 100 substrates is homogenized in the y direction, in addition to the homogenization of the processing over the whole extension of a substrate in the x direction (in accordance with FIG. 1B), via the constant mixing of process gases in every gas circulation cycle.

Differentially small gas volumes (2), (3) and (4) are considered on their flow path in two different instances of gas circulation for this in FIG. 1C. All of the differential gas volumes are labeled with corresponding reference numbers in circles in FIG. 1C. A first differential gas volume (2) goes from the gas inlet (13) to the plasma processing area through a first discharge opening (131a) here, crosses through a first plasma processing zone (11a) in the direction of the arrow, with its composition changing in the process, and leaves the plasma processing area as a differential gas volume (2′) through a first intake opening (141a) in the direction of the gas outlet (14). A second differential gas volume (3) correspondingly goes from the gas inlet (13) to the plasma processing area through a second discharge opening (131b), crosses through a second plasma processing zone (11b) in the direction of the arrow, with its composition changing in the process, and leaves the plasma processing area as a gas volume (3′) through a second intake opening (141b) in the direction of the gas outlet (14), whereas a third differential gas volume (4) goes from the gas inlet (13) to the plasma processing area through a third discharge opening (131c), crosses through a third plasma processing zone (11c) in the direction of the arrow, with its composition changing in the process, and leaves the plasma processing area as a differential gas volume (4′) through a third intake opening (141c) in the direction of the gas outlet (14).

In a first circulation cycle, the differential gas volumes (2), (3) and (4) all have a first gas composition (a) at first that is the same for all of the differential gas volumes (2), (3), and (4). While the individual differential gas volumes (2), (3) and (4) each cross through the corresponding plasma processing zone (11a to 11c), the overall composition for each differential gas volume changes in a special way depending on the characteristics of the plasma processing zone and the plasmas located in it. The plasma-chemical gas conversion can be somewhat different in the individual plasma zones, e.g. because of slightly different instances of plasma power coupling, which leads to a situation in which the differential gas volumes (2′), (3′) and (4′) can differ with regard to their gas composition after leaving the plasma zones.

As a result of that, the first differential gas volume (2′) has a first, slightly changed gas composition (a1), whereas the second differential gas volume (3′) has a second, slightly changed gas composition (a2) and the third differential gas volume (4′) has a third, slightly changed gas composition (a3) that can all differ from one another.

The differential gas volumes (2′), (3′) and (4′) are now mixed on their path through the circulation unit (30) so that there is a fourth differential gas volume (5) that has a fourth, homogenized gas composition (b) in the circulation line (31) in front of the connection to the gas supply line (21). The fourth differential gas volume (5) is mixed with fresh gas, if necessary, so a fifth differential gas volume (6) with a fifth gas composition (c) that can differ from the first gas composition (a) exists in the gas supply line (21).

This fifth differential gas volume (5) is now fed into the gas inlet (13) and, in a second cycle, fed into the corresponding plasma processing zones (11a to 11c) again as new differential gas volumes (2), (3) and (4) via the discharge openings (131a to 131c); the gas composition of the differential gas volumes (2), (3) and (4) among one another is equal once again.

A gas molecule that has gone through the first plasma processing zone (11a) in the first cycle can therefore go through the second plasma processing zone (11b), for instance, in the second cycle or through the third plasma processing zone (11c), which precisely brings about the intended gas-mixing effect. The processing rates and the layer properties that are obtained are therefore balanced out over all of the substrates whose process gases are mixed in the circulation unit (30).

The effects of gas recirculation through the gas circulation unit (30) that have been explained with regard to FIG. 1B and FIG. 1C arise in the same way in all of the embodiments of the device as per the invention.

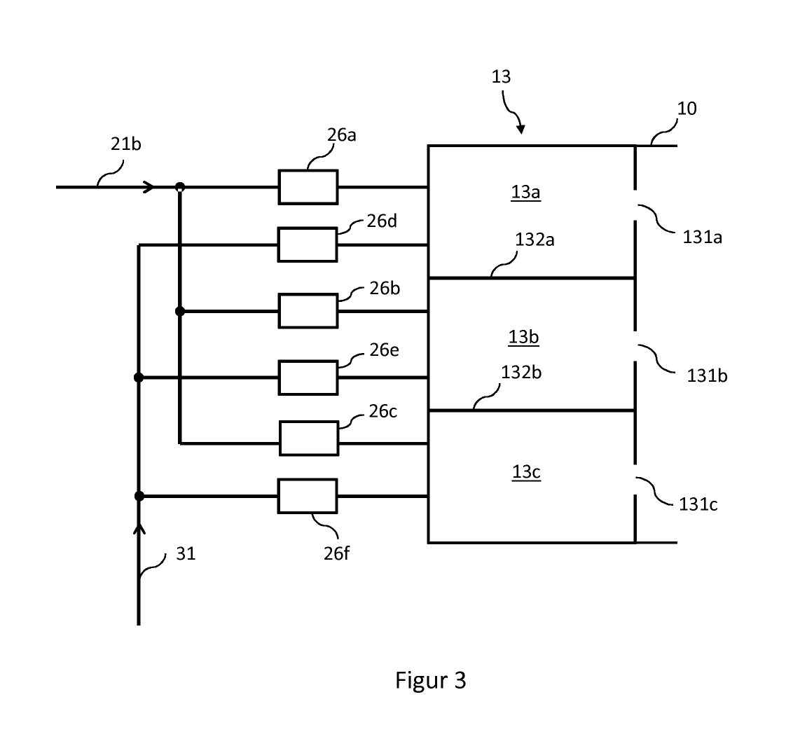

FIG. 2 shows a second embodiment of the device (1) for plasma processing as per the invention in a cross-section along the x-y plane. It has many commonalities with the first embodiment, so it does not have to be explained once again. In contrast to the first embodiment, the circulation unit (30) is, however, completely separated from the supply of fresh gas and the exhaust gas line connected to the pump (24). That means: The gas inlet (13) is connected to two gas supply lines (21a, 21b), and the gas outlet (14) is connected to two exhaust gas lines (23a, 23b). The first gas supply line (21a) corresponds to the circulation line (31), whereas the second gas supply line (21b) is connected to the gas provision unit (22) and serves to feed fresh gas, meaning a gas differing from the exhaust gas, into the gas inlet (13). The exhaust gas fed in through the first gas supply line (21a) and the fresh gas fed in through the second gas supply line (21b) are therefore first mixed in the gas inlet mixing chamber of the gas inlet (13).

In other embodiments, moreover, it is possible to provide further gas supply lines that feed further fresh gas into the gas inlet (13) in addition to the second gas supply line (21b). This is, in particular, advantageous when the freshly fed-in gases under normal pressure lead to problems with regard to safety when they are mixed.

The first exhaust gas line (23a) corresponds to the circulation line (31) and is directly connected to the circulation pump (32), whereas the second exhaust gas line (23b) is only connected to the pump (24). The gas outlet mixing chamber of the gas outlet (14) therefore has a sufficiently large cross-section in the x-y plane and thereby a sufficiently small key flow value in the interior, so the exhaust gases from the multiple plasma processing zones are thoroughly mixed. The gas flow of the exhaust gas that is fed once again into the gas inlet (13) is adjusted with the control valve (25a) arranged in the circulation line (31), whereas the pressure in the processing chamber (10) is adjusted with the control valve (25b) arranged in the second exhaust gas line (23b).

Features of the first and the second embodiments can also be combined. As an example, the device (1) for plasma processing can also comprise two gas supply lines (21a, 21b) as shown in FIG. 2, but only one exhaust gas line (23) as shown in FIG. 1.

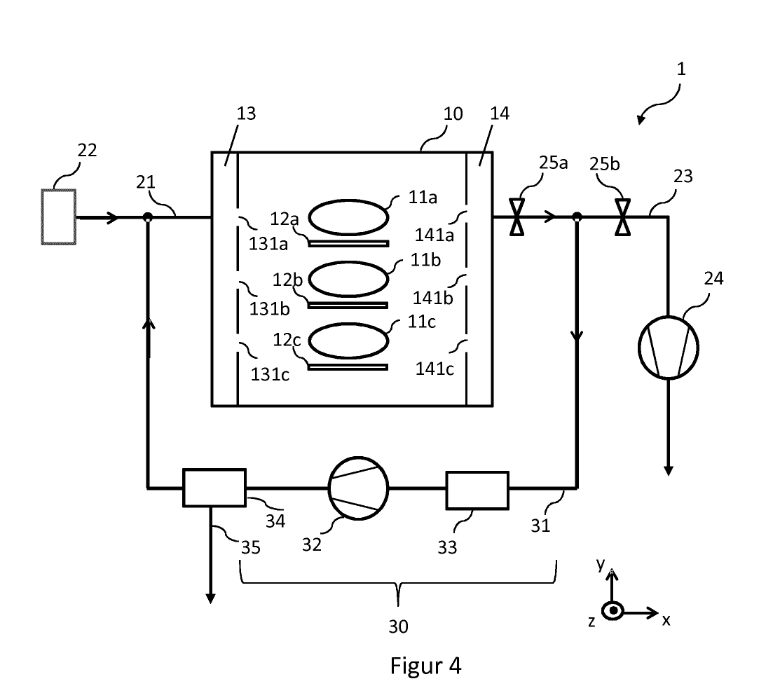

FIG. 3 shows an especially preferred embodiment of the gas inlet (13) and the gas supply in detail. First off, the gas inlet mixing chamber of the gas inlet (13) has several sub-chambers (13a to 13c) that are separated from one another via petition walls (132a, 132b). Each of the sub-chambers (13a to 13c) has its own discharge system that is represented by the discharge openings (131a to 131c). Each sub-chamber (13a to 13c) is connected to two gas supply lines; one line is suitable in each case for feeding fresh gas into the respective sub-chamber (13ato 13c), whereas the other one is suitable for feeding the exhaust gas supplied via the circulation line (31) into the respective sub-chamber (13a to 13c). Furthermore, a dispensing unit (26a to 26f) is arranged in each gas supply line with which the quantity of fresh gas fed into the respective sub-chamber (13a to 13c) and the quantity of exhaust gas fed into the respective sub-chamber (13a to 13c) are regulated. So the quantity of fresh gas fed into the sub-chamber 13a can be adjusted with the aid of the dispensing unit 26a, and the quantity of exhaust gas fed into the sub-chamber 13a can be adjusted with the aid of the dispensing unit 26d. Differences in the plasma processing conditions in the various plasma processing zones (11a to 11c) that are assigned in each case to a sub-chamber (13a to 13c) are therefore balanced out by a different composition of the process gas with the embodiment shown in FIG. 3.

Although a dispensing unit (26a to 26f) is shown in every gas supply line in each case in FIG. 3, dispensing units can also only be arranged in the gas supply lines for the supply of fresh gas or only arranged in the gas supply lines for the exhaust gas. Moreover, it is also possible for different fresh gasses to be fed into different sub-chambers (13a to 13c). Furthermore, it is possible for the individual sub-chambers (13a to 13c) of the gas inlet (13) to not be completely separated from one another with the petition walls (132a, 132b), but instead for these petition walls (132a, 132b) to have openings through which a gas can spread out in the overall gas inlet (13). The supply of exhaust gas can therefore be realized via only one gas supply line for all of the sub-chambers (13a to 13c), for instance, whereas the supply of fresh gas can be separately adjusted for each sub-chamber (13a to 13c).

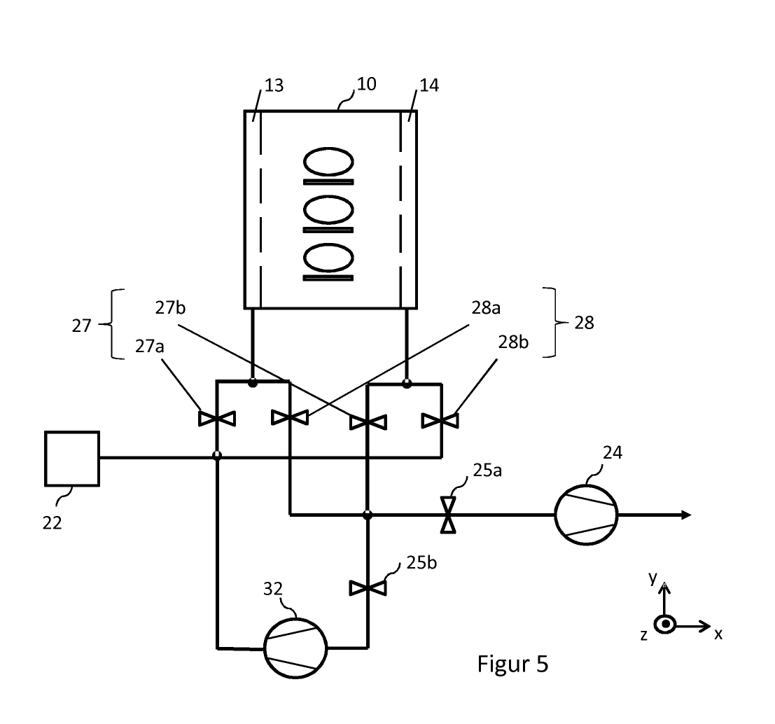

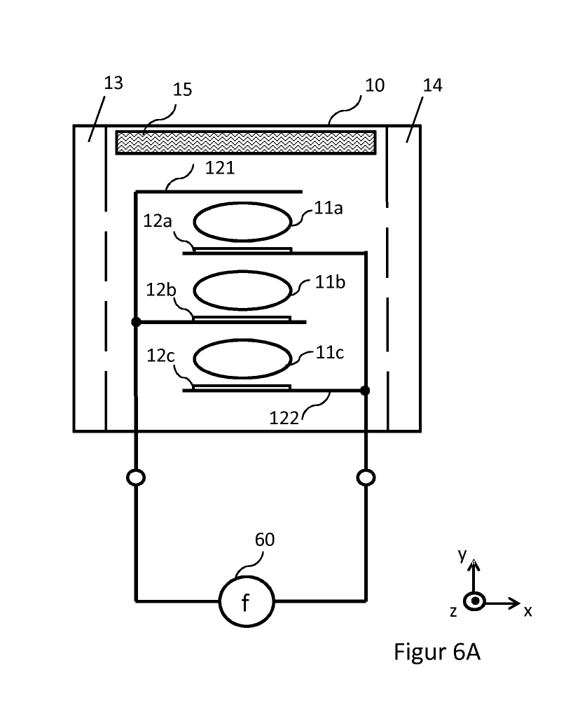

FIG. 4 schematically shows a third embodiment of the device (1) for plasma processing as per the invention. It corresponds in terms of the basic structure to the first embodiment, but the circulation unit (30) also comprises, in addition to the circulation line (31) and the circulation pump (32), a dust-collection device (33) and a device (34) for removing specific gaseous components of the exhaust gas. The dust-collection device (33) is advantageously arranged in front of the circulation pump (32) in the direction of the pumped gas so that dust particles that are contained in the exhaust gas will already be removed in front of the circulation pump (32) and negative effects on the pumping power will therefore be prevented.

In another advantageous embodiment, the dust-collection device (33) is arranged behind the circulation pump (32) in the direction of the pumped gas so that a drop in pressure in the dust-collection device (33) will have less of an impact. It is also possible for several dust-collection devices of that type or multi-stage devices to be used.

The device (34) for removing specific gaseous components of the exhaust gas serves to remove components of the exhaust gas that can no longer be used in the plasma processing or that exist in the exhaust gas in quantities that are too high. They could be reaction products, for instance, that no longer contribute to the actual plasma process to be carried out. These components can be removed in whole or in part from the exhaust gas transported in the circulation line (31) by the removal device (34) and carried off by a removal line (35). The device (34) for removing specific gaseous components of the exhaust gas can be arranged in front of or in back of the circulation pump (32) in the direction of the pumped gas in the circulation unit (30).

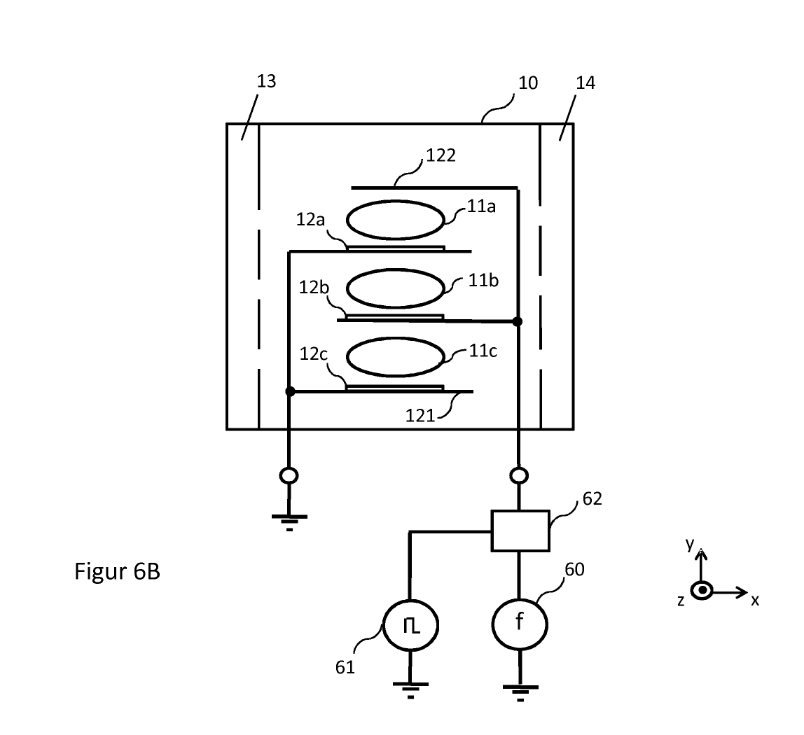

A fourth embodiment of the device (1) for plasma processing is schematically shown in FIG. 5 in which the direction of the flowing gas can be changed in the plasma processing zones. This is shown in the form of an example for the embodiment presented in FIG. 1 in which the gas inlet (13) is only connected to one gas supply line and the gas outlet (14) is only connected to one exhaust gas line. To reverse the direction of the gas flow, meaning in actual fact to exchange the gas inlet and the gas outlet with one another, a valve of a first valve group (27) and a valve of a second valve group (28) are arranged in each case in the gas supply line and the exhaust gas line. The first valve group (27) and the second valve group (28) jointly form a changeover unit. In a first switching state, the valves (27a and 27b) of the first valve group (27) are open and the valves (28a and 28b) of the second valve group (28) are closed. The fresh gas from the gas provision unit (22) and the exhaust gas recirculated through the circulation line (31) are therefore fed into the gas inlet (13), and the exhaust gas is carried off via the gas outlet (14) from the processing chamber. In a second switching state, the valves (27a and 27b) of the first valve group (27) are closed and the valves (28a and 28b) of the second valve group (28) are open. The fresh gas from the gas provision unit (22) and the exhaust gas recirculated through the circulation line (31) are therefore fed into the gas outlet (14), and the exhaust gas is carried off via the gas inlet (13) from the processing chamber. The gas inlet (13) and the gas outlet (14) advantageously have the same design for this. Instances of inhomogeneity of the plasma process can be reduced over the extension of the substrates in the direction of flow by changing the direction of gas flow in the plasma processing zones (11a to 11c). Typical rates of change of the direction of flow are 5 to 25 alternations for each complete instance of plasma processing, for instance for each deposit of a certain layer thickness on a substrate in a coating process.

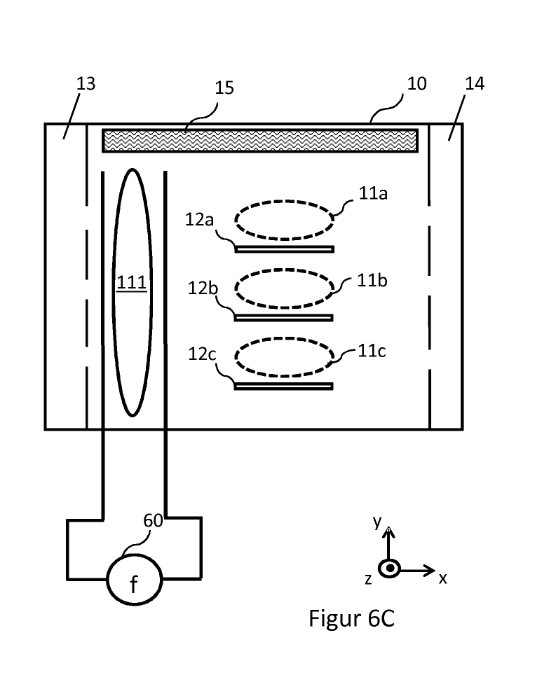

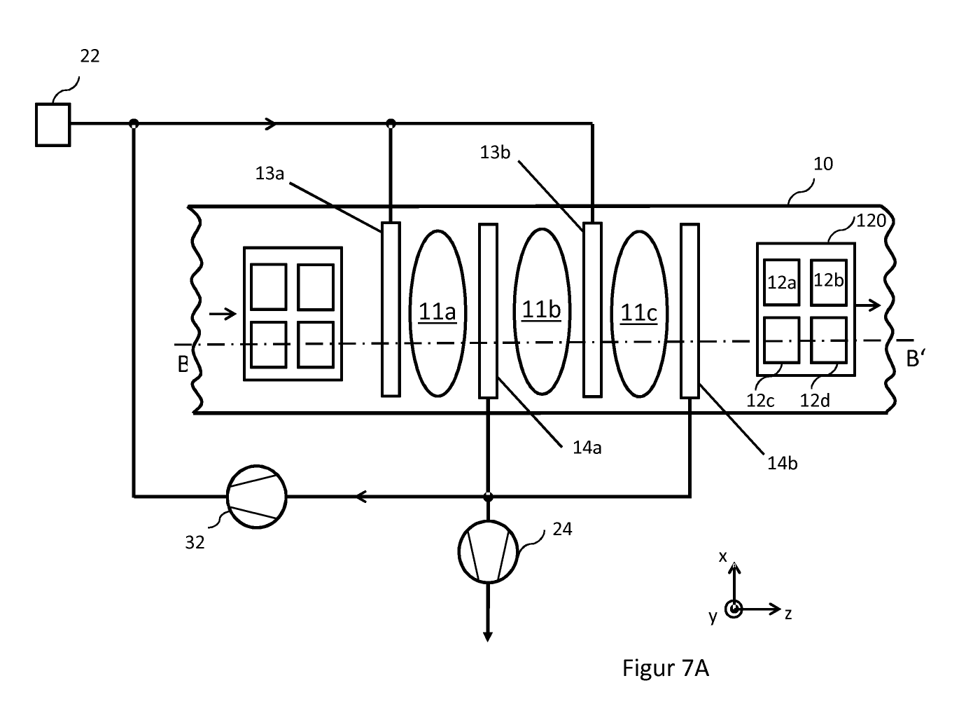

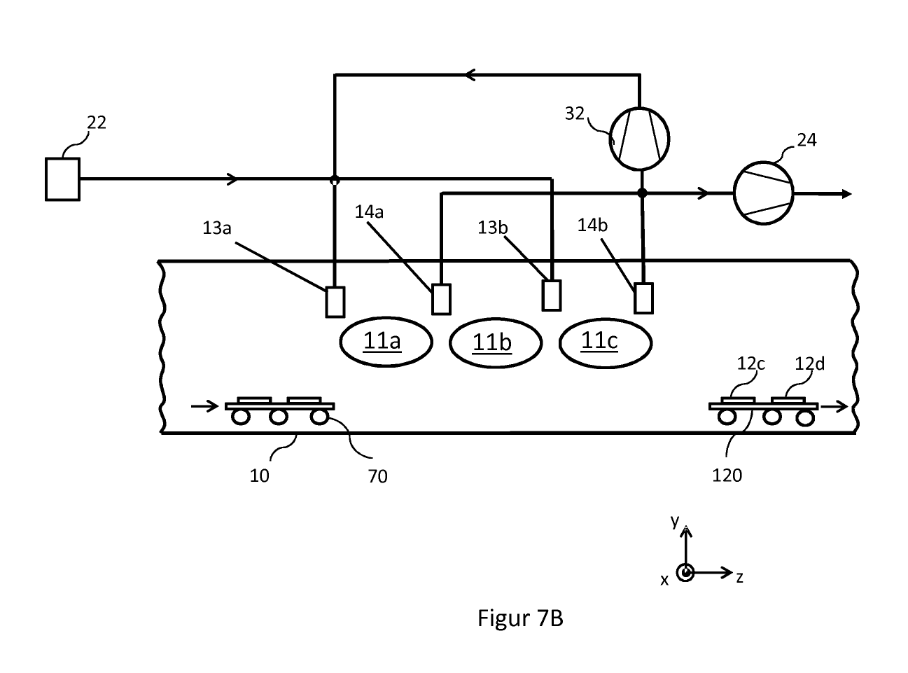

Specific examples of the production of plasma and the electrical connection of the substrate holders are explained with reference to FIGS. 6A to 6C; the first example of the device for plasma processing as per the invention is used. Details of the gas supply and the gas discharge have therefore been left out.

FIG. 6A shows an example of unpulsed plasma production using a generator (60) that provides a DC voltage. In other embodiments, the generator (60) can provide a low-frequency or high-frequency voltage. The substrates (12a to 12c) are arranged on electrodes (121, 122) that extend in a comb-like fashion. First electrodes (121) extend in the positive x direction here, whereas second electrodes (122) extend from a respective supply line in the negative x direction. In another embodiment, the electrodes (121, 122) extend in the positive and negative z direction from a corresponding supply line. The first electrodes (121) and the second electrodes (122) are arranged in an alternating fashion along the y direction the first electrodes (121) are electrically insulated from the second electrodes (122). The generator (60) is connected in a symmetrical fashion to the first and the second electrodes (121, 122). In other embodiments, the generator (60) is asymmetrically connected to the first and second electrodes (121, 122); the first electrodes (121) or the second electrodes (122) are grounded to the processing chamber. The electrodes (121, 122) have a somewhat greater lateral extension than that of the substrates (12a to 12c) arranged on them and typically have a spacing of 1 to 100 mm with respect to one another in the y direction. A plasma that makes the processing of the substrate between the electrodes possible between a first electrode (121) and a neighboring second electrode (122) is produced when a voltage is applied.

FIG. 6B shows an example of pulsed plasma production. The first electrodes (121) are grounded to the processing chamber (to earth) here, whereas the second electrodes (122) are connected to a match and filter box (62) to which a generator (60) and a pulse generator (61) are connected. A pulsed plasma that is produced in that fashion can be used for ion implementation via plasma immersion implantation. Doping agents such as boron or phosphorus with ion energies up to approx. 30 keV can therefore be implanted in a substrate. A plasma with the gas phosphine (PH3), for instance, or with boron trifluoride (BF3) is ignited in the plasma processing zones (11a to 11c) for that. Ions are accelerated from the plasma edge layer to the substrate via the application of short, negative, high-voltage pulses from the pulse generator (61).

FIG. 6B shows an example of remote plasma production. The plasma zone and the processing zone should be separated from one another for instances of processing in which no part of the ions from the plasma that are incident upon the substrate is necessary or desired, for instance for pure radical etching or surface modifications. Gas circulation as described in the previous examples is also advantageous here. The radicals and gas components produced in the remote plasma zone (111) are equally distributed here over the various processing zones (11a to 11c), which correspond to the previously described plasma processing zones in principle, so a reduction of the instances of inhomogeneity between different substrates (12a to 12c) and over the whole extension of a substrate is achieved. The remote plasma (111) can be produced via a generator (60), for instance.

In general, the plasma(s) used for the processing can be low-pressure plasmas for which the required power can be coupled in via electrodes, via an inductive process, via microwaves or via dielectric windows.

Furthermore, a heating element (15) that ensures the substrate temperature and/or gas temperature required for the plasma processing is also shown in FIGS. 6A and 6C. This can be realized, as an example, via infrared radiation or heat conduction. Heating elements are also advantageously integrated into the gas inlet mixing chamber and the gas outlet mixing chamber, so the substrates and the plasma processing zones will have a homogeneous temperature distribution. The heating elements that were described can be used in all of the embodiments of the device for plasma processing as per the invention.

FIGS. 7A and 7B show a fifth embodiment of the device for plasma processing as per the invention, wherein FIG. 7A shows a top view of the device and FIG. 7B shows a cross-section along the line B-B′ presented in FIG. 7A. The substrates (12a to 12d) in the processing chamber (10) move along a first direction, which corresponds to the z direction in the case that has been presented, in this embodiment of the device as per the invention. The movement is symbolized with the arrow. Multiple substrates (12a to 12d) can be laterally arranged next to one another on a substrate carrier (120) here. The substrate carrier (120) is moved via a device (70) for moving the substrates in the processing chamber. This could be the rollers shown in FIG. 7B, for instance, or a belt or other device. The processing chamber has several gas inlets (13a, 13b) and several gas outlets (14a, 14b); they are arranged in an alternating fashion along the first direction on one side of the processing chamber. As can be seen in FIG. 7B, the gas inlets (13a, 13b) and the gas outlets (14a, 14b) are arranged along the upper chamber wall. A plasma processing zone (11a to 11c) is arranged between a gas inlet (13a, 13b) and its neighboring gas outlet (14a, 14b) (or two neighboring gas outlets); the substrates (12a to 12d) are guided along beneath the plasma processing zones (11a to 11c). The process gases do in fact, therefore, flow to the arrangement of substrates (12a to 12d), but not through it.

The exhaust gases that leave all of the gas outlets (14a, 14b) located in the processing chamber (10) are advantageously mixed with one another and fed into all of the gas inlets (13a, 13b) located in the processing chamber (10). It is also possible in other embodiments, however, to only mix the exhaust gases from specific gas outlets and to only feed them into specific gas inlets. Process-gas differences between the individual plasma processing zones (11a to 11c), but also within a specific plasma processing zone, are balanced out by the mixture of exhaust gases and their renewed supply to the gas inlets.

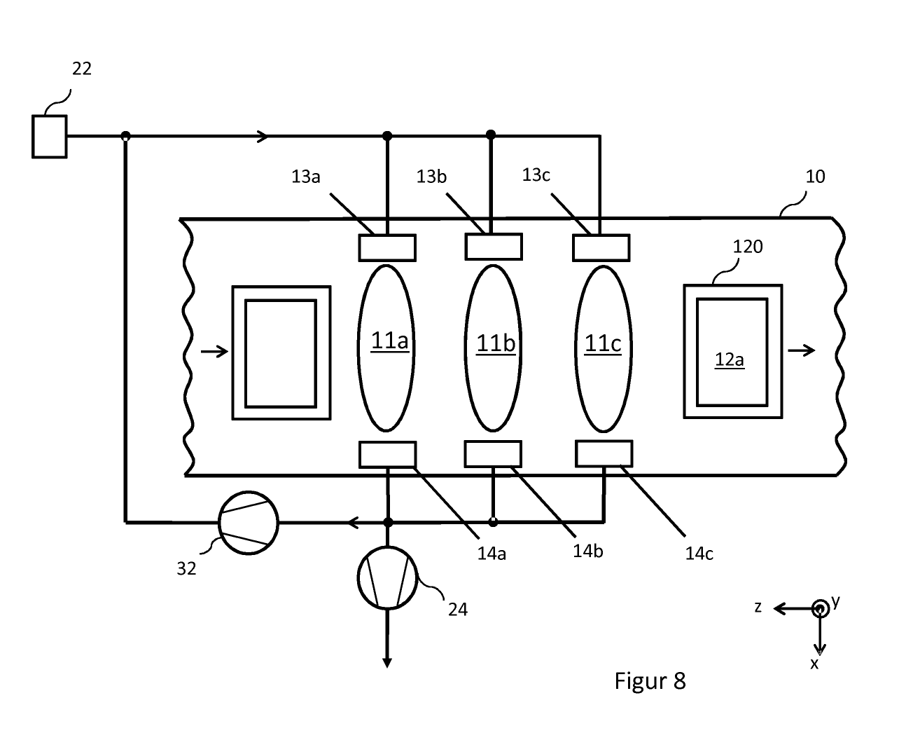

FIG. 8 shows a sixth embodiment of the device for plasma processing as per the invention in a top view of the device; FIG. 1 presents an example of a cross-section of a device of that type along the x-y plane. The substrates are also moved along the first direction, meaning along the z direction, in the processing chamber (10) here. But the substrates are arranged vertically, meaning along the y direction, on top of one another in a substrate carrier (120), so only the topmost substrate (12a) can be seen in the top view. The processing chamber is comprised of several gas inlets (13a to 13c) and several gas outlets (14a to 14c) that are arranged along the first direction on opposite sides of the processing chamber; each gas inlet is assigned to one gas outlet. A specific gas inlet (e.g. 13a) is arranged on one side of the processing chamber (10) here, and the gas outlet (e.g. 14a) assigned to this specific gas inlet is arranged on the opposite side of the processing chamber. The process gas therefore flows through the substrate arrangement and the plasma processing zone (e.g. 11a) assigned to the respective gas inlet and gas outlet. The two sides of the processing chamber are spaced apart from one another here in the x direction. In the embodiment shown in FIG. 8, all of the gas inlets (13a to 13c) are arranged on one side of the processing chamber (10) and all of the gas outlets (14a to 14c) are arranged on the opposite side of the processing chamber (10).

But individual pairs made up of one gas inlet and one gas outlet can also be arranged opposite one another in other embodiments. As an example, the gas inlets 13a and 13c can be arranged on a first side of the processing chamber (10) and the accompanying gas outlets 14a and 14c on the opposite, second side of the processing chamber (10), whereas the gas inlet 13b is arranged on the second side of the processing chamber (10) and the accompanying gas outlet 14b is arranged on the first side of the processing chamber (10). A change of the direction of gas flow can therefore be achieved in neighboring plasma processing zones (11a to 11c) without using the changeover unit shown in FIG. 5.

In examples other than the ones shown in FIGS. 7A, 7B and 8, the number of gas inlets and gas outlets, their arrangement with regard to the sides of the processing chamber (10) and the number of exhaust gases mixed with one another or, as the case may be, the number of gas outlets and gas inlets interconnected with one another, can differ from those in the examples shown in the figures.

### LIST OF REFERENCE NUMERALS

1 Device for plasma processing

2-6 Differential gas volume

10 Processing chamber

11a-11c Plasma processing zone

111 Remote plasma

12a-12d Substrate

120 Substrate carrier

121 First electrodes

122 Second electrodes

13 Gas inlet

13a-13c Sub-chamber

131a-131c Discharge opening

132a,b Partition wall

14 Gas outlet

141a-141c Intake opening

15 Heating element

21 Gas supply line

21a First gas supply line

21b Second gas supply line

22 Gas provision unit

23 Exhaust gas line

23a First exhaust gas line

23b Second exhaust gas line

24 Pump

25a, 25b Control valve

26a-26f Dispensing unit

27 First valve group

24a,b Valves of the first valve group

28 Second valve group

28a,b Valves of the second valve group

30 Circulation unit

31 Circulation line

32 Circulation pump

33 Dust-collection device

34 Device for removing gas components

35 Removal line

60 Generator

61 Pulse generator

62 Match and filter box

70 Device for the movement of substrates

1. Device for plasma processing, comprising:
a processing chamber with:
at least two plasma processing zones with process gas flowing through them,
a gas inlet that is suitable for feeding the process gas into the at least two plasma processing zones, and
a gas outlet that is suitable for discharging an exhaust gas from the processing chamber, and
a circulation unit with a circulation line and a circulation pump, wherein the circulation unit is suitable for feeding at least a portion of the exhaust gas into the gas inlet,
wherein the exhaust gas fed into the gas inlet is a mixture of gases that are discharged from at least two of the plasma processing zones.

2. Device for plasma processing according to claim 1, characterized in that
the circulation unit includes a control valve, and
the control valve and the circulation pump are designed in such a way that the ratio of the gas flow of the exhaust gas fed into the gas inlet via the circulation line to the gas flow of a gas differing from the exhaust gas that is fed into the gas inlet is in a range less than or equal to 100, preferably 10.

3. Device for plasma processing according to claim 1, characterized in that the gas inlet is connected to a gas supply line that is connected to a device for providing a gas differing from the exhaust gas, wherein the circulation line is connected to the gas supply line so that the exhaust gas supplied by the circulation unit is fed into the gas inlet via the gas supply line.

4. Device for plasma processing according to claim 1, characterized in that the gas inlet is connected to two gas supply lines, wherein a first gas supply line is directly connected to the circulation line and a second gas supply line is connected with a device for providing a gas differing from the exhaust gas.

5. Device for plasma processing according to claim 1, characterized in that the gas inlet is realized by a gas inlet mixing chamber that has at least two discharge systems, each with one or more openings, from which the process gas flows to the plasma processing zones, wherein each discharge system is assigned in each case to one of the at least two plasma processing zones.

6. Device for plasma processing according to claim 5, characterized in that the openings of the at least two discharge systems have an identical key value.

7. Device for plasma processing according to claim 4, characterized in that the gas inlet is realized by a gas inlet mixing chamber that has at least two sub-chambers, wherein each sub-chamber has a separate discharge system from which the process gas flows to at least one plasma processing zone and which is assigned to at least one of the plasma processing zones in each case, wherein each sub-chamber is assigned to at least one dispensing unit that is suitable for separately adjusting the fed-in exhaust gas and/or the quantity of the fed-in gas differing from the exhaust gas for the respective sub-chamber.

8. Device for plasma processing according to claim 1, characterized in that the gas outlet is realized by a gas outlet mixing chamber that has at least two intake systems, each with one or several openings through which the exhaust gas from the plasma processing zones flows into the gas outlet mixing chamber, wherein each intake system is assigned to one of the at least two plasma processing zones.

9. Device for plasma processing according to claim 8, characterized in that the openings of the at least two intake systems have an identical key value.

10. Device for plasma processing according to claim 1, characterized in that
the gas outlet is connected to a device for discharging gas through the exhaust gas line, and
the circulation line is connected to the exhaust gas line.

11. Device for plasma processing according to claim 1, characterized in that the gas outlet is connected to a device for gas discharge through an exhaust gas line and, separately from that, is connected to the circulation line.

12. Device for plasma processing according to claim 1, characterized in that the circulation unit includes a dust-collection device.

13. Device for plasma processing according to claim 1, characterized in that the circulation unit includes a device for removing specific components of the exhaust gas.

14. Device for plasma processing according to claim 1, characterized in that
the gas inlet and the gas outlet have an identical design and
the device for plasma processing has a changeover unit that is suitable, in a first switching state, to supply the gas inlet with exhaust gas fed in through the circulation line and the fed-in gas differing from the exhaust gas, and to discharge the exhaust gas from the gas outlet, and, in a second switching state, to supply the gas outlet with exhaust gas fed in through the circulation line and the fed-in gas differing from the exhaust gas, and to discharge the exhaust gas from the gas inlet.

15. Device for plasma processing according to claim 14, characterized in that the changeover unit is suitable for changing the switching state between 5 and 25 times per plasma processing event.

16. Device for plasma processing according to claim 1, characterized in that
the device for plasma processing has, moreover, a device for moving an arrangement of substrates that are processed in the plasma processing zones along a first direction in the processing chamber and
the processing chamber includes several gas inlets and several gas outlets, wherein the gas inlets and the gas outlets are arranged in an alternating fashion along the first direction on one side of the processing chamber and the process gas flows to the substrate arrangement, but not through it.

17. Device for plasma processing according to claim 1, characterized in that the gas inlet and the gas outlet are arranged on opposite sides of the processing chamber.

18. Device for plasma processing according to claim 1, characterized in that
the device for plasma processing has, moreover, a device for moving an arrangement of substrates that are processed in the plasma processing zones along a first direction in the processing chamber and
the processing chamber includes several pairs of gas inlets and gas outlets assigned to them, wherein the gas inlets and the gas outlets are arranged along the first direction to the effect that a specific gas inlet is arranged on one side of the processing chamber that extends along a first direction and the gas outlet assigned to this specific gas inlet is arranged on the opposite side of the processing chamber so that the process gas flows through the substrate arrangement and the plasma processing zones assigned to the respective gas inlet and gas outlet.

19. Device for plasma processing according to claim 18, characterized in that the device for plasma processing is comprised of exactly the same number of circulation units as there are pairs of gas inlets and gas outlets assigned to them, wherein a circulation unit is assigned to each specific pair made up of a gas inlet and an assigned gas outlet and wherein the exhaust gases from a specific gas outlet are exclusively fed into the assigned gas inlet via the assigned circulation unit.

20. Device for plasma processing according to claim 18, characterized in that the exhaust gases from all of the gas outlets are mixed and fed into all of the gas inlets.

21. Device for plasma processing according to claim 18, characterized in that the gas inlets and the accompanying gas outlets of two pairs of gas inlets and gas inlets assigned to them that are arranged in back of one another in the first direction are arranged in such a way that the gas inlet of the one pair is located on the same side of the processing chamber as the gas outlet of the other pair.
